(19) United States
(12) Patent Application Publication
(10) Pub. No.: US 2021/0405785 A1
(43) Pub. Date: Dec. 30, 2021

(54) RESISTIVE TOUCH SCREEN AND FLEXIBLE DISPLAY DEVICE

(71) Applicant: Wuhan China Star Optoelectronics Semiconductor Display Technology Co., Ltd., Wuhan, Hubei (CN)

(72) Inventors: Yi Li, Wuhan, Hubei (CN); Qibing Dai, Wuhan, Hubei (CN)

(73) Assignee: Wuhan China Star Optoelectronics Semiconductor Display Technology Co., Ltd., Wuhan, Hubei (CN)

(21) Appl. No.: 16/651,486

(22) PCT Filed: Nov. 19, 2019
(86) PCT No.: PCT/CN2019/119400

§ 371 Date: Mar. 27, 2020

(30) Foreign Application Priority Data
Sep. 17, 2019 (CN) 201910875067.2

(51) Int. Cl. G06F 3/045

(52) U.S. Cl. CPC G06F 3/045; H01L 51/5281; G06F 2203/04104; G06F 2203/04102

(57) ABSTRACT

The disclosure provides a resistive touch screen and a flexible display device. In the flexible display device, the resistive touch screen replaces a capacitive touch screen, and materials and structures of the resistive touch screen are improved. A problem that touch accuracy of conventional capacitive touch screens is low is solved, and the flexible display device having high accuracy, an ability to detect multiple touch points, and a long lifetime can be realized.

### FIELD

The present disclosure relates to the field of touch control display panel and, more particularly, relates to a resistive touch screen and a flexible display device.

### BACKGROUND

Presently, most panel manufacturers choose capacitive touch screens to be applied to panels among touch screens. In capacitive touch screens, a position of a touch point is confirmed by detecting changes in capacitance between sensors and between sensors and ground when a finger touches a screen. The capacitive touch screens have advantages such as operation flexibility and ability to detect multiple touch points. However, in dynamically flexible touch screens, a screen surface is covered by a flexible cover film. A surface of the cover film is deformed when a finger touches a screen, but a distance between fingers and a sensor cannot be fixed because of different finger pressures. Therefore, changes in capacitance between sensors and between sensors and ground when a finger touches a screen cannot be confined within a certain range, thereby reducing touch accuracy of capacitive touch screens and affecting performance of dynamically flexible touch screens.

### SUMMARY

To overcome shortcomings in conventional technology, in the present disclosure, a resistive touch screen replaces a capacitive touch screen which is more common in market and is applied to a flexible display device. Unlike conventional resistive touch screens, a glass on a touch surface is substituted by a flexible cover film, which satisfies a flexibility requirement of flexible display devices. A deformation of the cover film can conveniently provide a deformation needed by a conductive layer of the resistive touch screen, thereby precisely detecting a position of a touch point. Furthermore, resistive touch screens are less affected by environment and have high stability.

To solve the above problem, the present provides a resistive touch screen, including: a substrate; a first conductive layer disposed on the substrate; a plurality of spacer points disposed on the first conductive layer; and a film assembly disposed on the spacer points. The film assembly includes a cover film and second conductive layer disposed on a bottom side of the cover film, and the second conductive layer is disposed on a same plane, and a material of the second conductive layer is a nanosilver line or a carbon nanotube.

According to one embodiment of the present disclosure, a material of the second conductive layer is a nanosilver line or a carbon nanotube.

According to one embodiment of the present disclosure, materials of the spacer points are transparent insulating resins.

According to one embodiment of the present disclosure, in a first direction, an end of the first conductive layer is connected to an electrode configured to provide an input voltage.

According to one embodiment of the present disclosure, in the first direction, another end of the first conductive layer is connected to an electrode configured to connect to ground.

According to one embodiment of the present disclosure, in a second direction perpendicular to the first direction, an end of the second conductive layer is connected to an electrode configured to provide an input voltage.

According to one embodiment of the present disclosure, in the second direction, another end of the second conductive layer is connected to an electrode configured to connect to ground.

According to one embodiment of the present disclosure, a material of the cover film is polyimide.

According to one embodiment of the present disclosure, a number of the second conductive layer is plural.

According to one embodiment of the present disclosure, the second conductive layers are parallel to and evenly spaced apart from each other on the bottom side of the cover film.

According to one embodiment of the present disclosure, the second conductive layers are patterned to be strip-shaped.

According to one embodiment of the present disclosure, an end of each of the second conductive layers is connected to a metal wire configured to provide an input voltage.

According to one embodiment of the present disclosure, each of the second conductive layers corresponds to a different input voltage.

According to one embodiment of the present disclosure, another end of each of the second conductive layers is connected to an electrode configured to connect to ground.

According to one embodiment of the present disclosure, in a direction perpendicular to an extending direction of the second conductive layers, an end of the first conductive layer is connected to an electrode configured to provide an input voltage.

According to one embodiment of the present disclosure, in the direction perpendicular to the extending direction of the second conductive layers, another end of the first conductive layer is connected to an electrode configured to connect to ground.

To solve the above problem, the present disclosure further provides a flexible display device, including: an organic light-emitting diode (OLED) device; a polarizer disposed on the OLED device; and the resistive touch screen disposed on the polarizer.

According to one embodiment of the present disclosure, the OLED device includes a substrate, and an anode, a hole transport layer, a luminescent layer, an electron transport layer, and a cathode, which are sequentially disposed on the substrate.

According to one embodiment of the present disclosure, the polarizer is attached to the OLED device by an optically clear adhesive.

According to one embodiment of the present disclosure, the polarizer is attached to the resistive touch screen by an optically clear adhesive.

Regarding the beneficial effects: the present disclosure provides a flexible display device having a resistive touch screen, which has better touch accuracy than that of flexible display devices having a capacitive touch screen. Furthermore, different from conventional resistive touch screens, in the present disclosure, a touch surface of the resistive touch screen is a flexible cover film, and a material of a conductive of the resistive touch screen is a nanosilver line or a carbon nanotube which have better bendability instead of indium tin oxide, thereby effectively extending lifetime of the flexible display device having the resistive touch screen provided by the present disclosure. Moreover, since bendability is improved, the conductive layer of the resistive touch screen provided by the present disclosure can be strip-shaped, which realizes a flexible display device with an ability to detect multiple touch points, high touch accuracy, and a long lifetime.

### DESCRIPTION OF DRAWINGS

The accompanying figures to be used in the description of embodiments of the present disclosure or prior art will be described in brief to more clearly illustrate the technical solutions of the embodiments or the prior art. The accompanying figures described below are only part of the embodiments of the present disclosure, from which those skilled in the art can derive further figures without making any inventive efforts.

FIG. 1 is a schematic view showing a structure of a resistive touch screen provided by a first embodiment of the present disclosure.

FIG. 2 is top views showing a first conductive layer and a second conductive layer of the resistive touch screen provided by the first embodiment of the present disclosure.

FIG. 3 is a schematic view showing a structure of a flexible display device provided by a second embodiment of the present disclosure.

FIG. 4 is a schematic view showing a structure of an OLED device of the flexible display device provided by the second embodiment of the present disclosure.

FIG. 5 is a schematic view showing a structure of a resistive touch screen provided by a third embodiment of the present disclosure.

FIG. 6 is a bottom view showing a film assembly of the resistive touch screen provided by the third embodiment of the present disclosure.

FIG. 7 is a schematic view showing a structure of a flexible display device provided by a fourth embodiment of the present disclosure.

FIG. 8 is a schematic view showing a structure of an OLED device of the flexible display device provided by the fourth embodiment of the present disclosure.

### DETAILED DESCRIPTION

The following description of the various embodiments is provided with reference to the accompanying drawings. It should be understood that terms such as “upper”, “lower”, “front”, “rear”, “left”, “right”, “inside”, “outside”, “clockwise”, “lateral”, as well as derivative thereof should be construed to refer to the orientation as then described or as shown in the drawings under discussion. These relative terms are for convenience of description, do not require that the present disclosure be constructed or operated in a particular orientation, and shall not be construed as causing limitations to the present disclosure. In the drawings, the identical or similar reference numerals constantly denote the identical or similar elements or elements having the identical or similar functions.

The present disclosure solves a technical problem that conventional flexible display devices having a capacitive touch screen have low touch accuracy. Materials and structures of conventional resistive touch screens are improved by the following embodiments and are applied to a flexible display device. Not only can the above technical problem be solved, but also a flexible display device with an ability to detect multiple touch points, high touch accuracy, and a long lifetime can be realized.

### First Embodiment

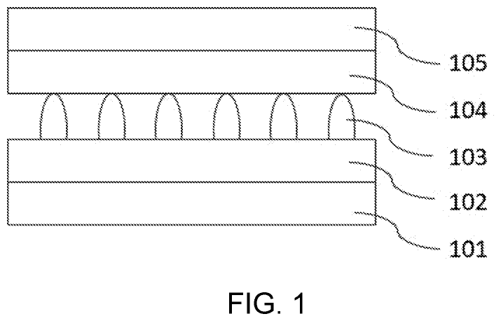

As shown in FIG. 1, to solve the above problem, the present disclosure provides a resistive touch screen, including: a substrate 101; a first conductive layer 102 disposed on the substrate 101; a plurality of spacer points 103 disposed on the first conductive layer 102, wherein the spacer points 103 form an array; a second conductive layer 104 disposed on the spacer points 103; and a cover film 105 disposed on the second conductive layer 104.

In the present embodiment, a touch surface of the resistive touch screen is the flexible cover film 105. A material of the flexible cover film 105 may be transparent materials such as polyimide. Materials of the spacer points 103 may be insulating transparent resins. Materials of the first conductive layer 102 and the second conductive layer 104 are nanosilver lines or carbon nanotubes. Compared with indium tin oxide (ITO), which is a material of a conductive layer of conventional resistive touch screens, nanosilver lines and carbon nanotubes have better bendability and are more suitable to be applied to devices that are frequently bent. As a result, the resistive touch screen provided by the present disclosure has exceptional bendability.

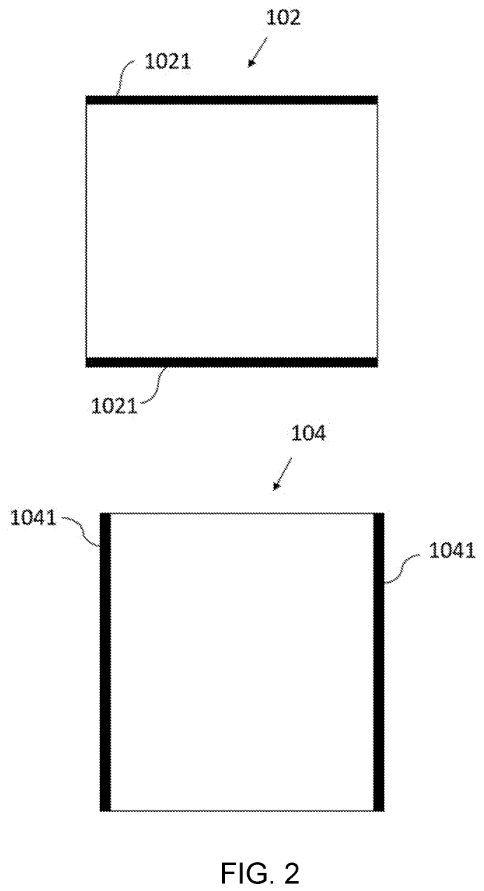

Specifically, as shown in FIG. 1 and FIG. 2, in a first direction, two ends of the first conductive layer 102 are respectively connected to two electrodes 1021, wherein a reference voltage is applied to one electrode 1021, and the other electrode 1021 is connected to ground. In a second direction, two ends of the second conductive layer 104 are respectively connected to two other electrodes 1041, wherein a reference voltage is applied to one electrode 1041, and the other electrode 1041 is connected to ground. Therefore, an electric field is formed between the first conductive layer 102 and the second conductive layer 104, wherein the first direction is perpendicular to the second direction. When the touch film 105 is pressed and deformed by fingers or touch pens, the second conductive layer 104 is also deformed to contact the first conductive layer 102. Meanwhile, electrical resistances of the second conductive layer 104 and the first conductive layer 102 are changed. When the change is detected by the touch screen, coordinates of a touch point on the first conductive layer 102 and the second conductive layer 104 can be respectively tracked, thereby concisely confirming a position of the touch point on the cover film 105.

### Second Embodiment

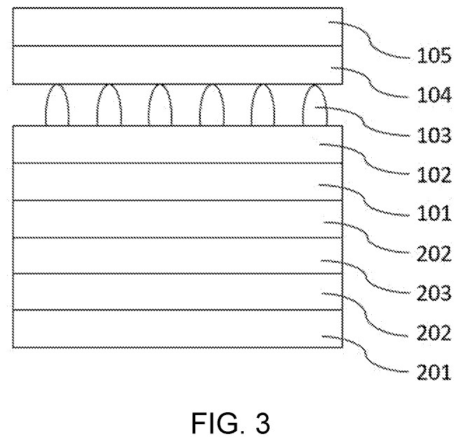

As shown in FIG. 3, to solve the above problem, the present disclosure further provides a flexible display device, including: an organic light-emitting diode (OLED) device 201; a polarizer 203 disposed on the OLED device 201; and the resistive touch screen of the first embodiment disposed on the polarizer 203.

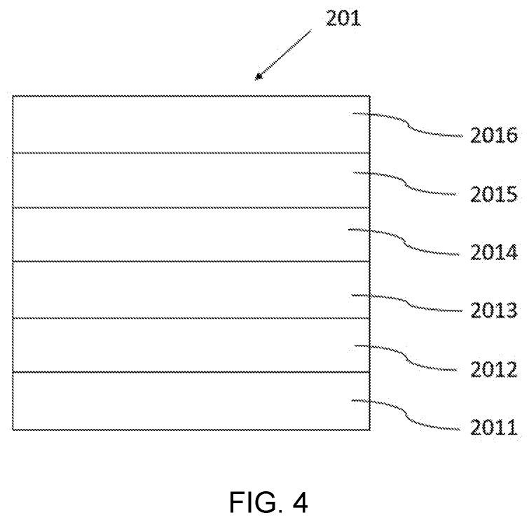

As shown in FIG. 3 and FIG. 4, in the present embodiment, the OLED device 201 may further include a substrate 2011, and an anode 2012, a hole transport layer 2013, a luminescent layer 2014, an electron transport layer 2015, and a cathode layer 2016, which are sequentially disposed on the substrate 2011. The OLED device 201 and the polarization layer 203 are connected by an optically clear adhesive (OCA) 202, and the polarizer 203 and the resistive touch screen are also connected by an OCA 202. Specifically, the polarizer 203 and a substrate 101 of the resistive touch screen are connected by the OCA 202. Structures of the resistive touch screen are same as the structures of the resistive touch screen provided by the first embodiment and are not described here again.

As shown in FIG. 3, because the resistive touch screen having exceptional bendability provided by the first embodiment is applied to the flexible display device provided by the present embodiment, the flexible display device also has exceptional bendability, and lifetime of the flexible display device is extended. In addition, because a touch surface of the resistive touch screen is the cover film 105, the flexible display device provided by the present disclosure may be flexible. When the touch film 105 is pressed and deformed by fingers or touch pens, a deformation of the cover film 105 can conveniently provide a deformation needed by the conductive layer 104 of the resistive touch screen. Specifically, as shown in FIG. 2 and FIG. 3, in a first direction, two ends of the first conductive layer 102 are respectively connected to two electrodes 1021, wherein a reference voltage is applied to one electrode 1021, and the other electrode 1021 is connected to ground. In a second direction, two ends of the second conductive layer 104 are respectively connected to two other electrodes 1041, wherein a reference voltage is applied to one electrode 1041, and the other electrode 1041 is connected to ground. Therefore, an electric field is formed between the first conductive layer 102 and the second conductive layer 104, wherein the first direction is perpendicular to the second direction. When the touch film 105 is pressed and deformed by fingers or touch pens, the second conductive layer 104 is also deformed to contact the first conductive layer 102. Meanwhile, electrical resistances of the second conductive layer 104 and the first conductive layer 102 are changed. When the change is detected by the touch screen, coordinates of a touch point on the first conductive layer 102 and the second conductive layer 104 can be respectively tracked, thereby concisely confirming a position of the touch point on the cover film 105. The flexible display device provided by the present disclosure has high touch accuracy and a long lifetime.

### Third Embodiment

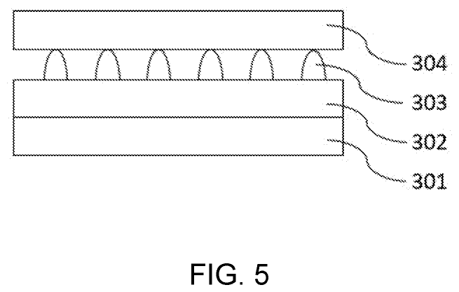

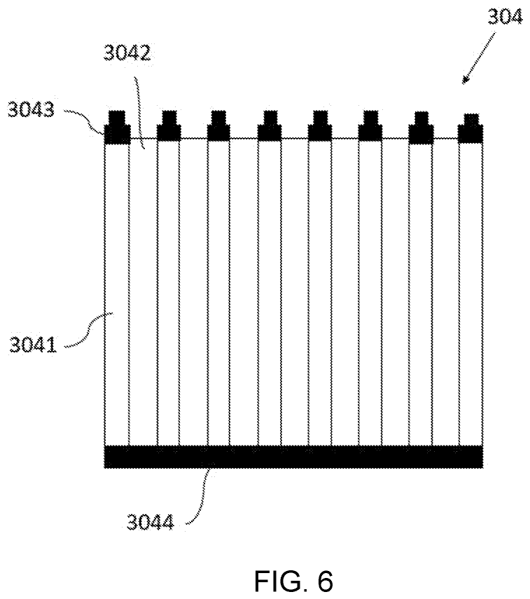

As shown in FIG. 5 and FIG. 6, to solve the above problem, the present disclosure further provides a resistive touch screen, including: a substrate 301; a first conductive layer 302 disposed on the substrate 301; a plurality of spacer points 303 disposed on the first conductive layer 302, wherein the spacer points 303 form an array; and a film assembly 304, wherein the film assembly 304 includes a cover film 3042 and a plurality of second conductive layers 3041 disposed on a bottom side of the cover film 3042, and the second conductive layers 3041 are disposed on a same plane.

Materials of the second conductive layers 3041 are nanosilver lines or carbon nanotubes.

In the present embodiment, a material of the first conductive layer 302 is a nanosilver line or a carbon nanotube.

In the present embodiment, a touch surface of the resistive touch screen is the flexible cover film 3042. A material of the flexible cover film 3042 may be transparent materials such as polyimide. Materials of the spacer points 303 may be insulating transparent resins. Materials of the first conductive layer 302 and the second conductive layers 3041 are nanosilver lines or carbon nanotubes. Compared with indium tin oxide (ITO) which is a material of a conductive of conventional resistive touch screens, nanosilver lines and carbon nanotubes have better bendability and are more suitable to be applied to devices that are frequently bent. As a result, the resistive touch screen provided by the present disclosure has exceptional bendability.

In the present embodiment, because the second conductive layers 3041 are made of nanosilver lines or carbon nanotubes which have exceptional bendability, the second conductive layers 3041 can be patterned to be strip-shaped as shown in FIG. 6. The second conductive layers 3041 are parallel to and evenly spaced apart from each other on the bottom side of the cover film 3042 and are disposed on a same plane. An end of each of the second conductive layers 3041 is connected to a metal wire 3043 configured to provide an input voltage, while each of the second conductive layers 3041 corresponds to a different input voltage. The other end of each of the second conductive layers 3041 is connected to an electrode 3044 configured to connect to ground. In a direction perpendicular to an extending direction of the second conductive layers 3041, two ends of the first conductive layer 302 are respectively connected to two other electrodes, wherein one electrode is configured to provide a reference voltage, and the other electrode is configured to connect to ground, as shown in FIG. 5 and FIG. 6. When the cover film 3042 is pressed and deformed by fingers or touch pens, the second conductive layer 3041 is also deformed to contact the first conductive layer 302. Meanwhile, electrical resistances of the second conductive layer 3041 and the first conductive layer 302 are changed. When the change is detected by the touch screen, coordinates of a touch point on the first conductive layer 302 and the second conductive layers 3041 can be respectively tracked, thereby concisely confirming a position of the touch point on the cover film 3042. Different from the first embodiment, in the present embodiment, different reference voltages correspond to different second conductive layers 3041, thereby concisely confirming positions of touch points on different second conductive layers 3041. Therefore, multiple touch points can be accurately detected.

### Fourth Embodiment

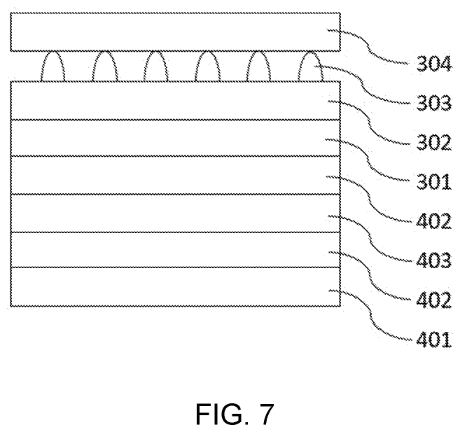

As shown in FIG. 7, to solve the above problem, the present disclosure further provides a flexible display device, including: an OLED device 401; a polarizer 403 disposed on the OLED device 401; and the resistive touch screen of the third embodiment disposed on the polarizer 403.

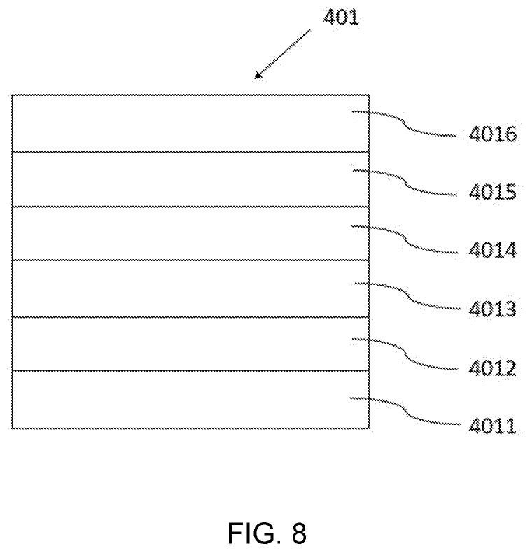

As shown in FIG. 7 and FIG. 8, in the present embodiment, the OLED device 401 may further include a substrate 4011, and an anode 4012, a hole transport layer 4013, a luminescent layer 4014, an electron transport layer 4015, and a cathode layer 4016, which are sequentially disposed on the substrate 4011. The OLED device 401 and the polarization layer 403 are connected by an optically clear adhesive (OCA) 402, and the polarizer 403 and the resistive touch screen are also connected by an OCA 402. Specifically, the polarizer 403 and a substrate 401 of the resistive touch screen are connected by the OCA 402. Structures of the resistive touch screen are same as the structures of the resistive touch screen provided by the third embodiment and are not described here again.

Because the resistive touch screen having exceptional bendability provided by the third embodiment is applied to the flexible display device provided by the present embodiment, the flexible display device also has exceptional bendability, and lifetime of the flexible display device is extended. In addition, because a touch surface of the resistive touch screen is the cover film 3042, the flexible display device provided by the present disclosure may be flexible. As shown in FIG. 6, when the touch film 3042 is pressed and deformed by fingers or touch pens, a deformation of the cover film 3042 can conveniently provide a deformation needed by the second conductive layers 3041 of the resistive touch screen. As a result, touch points can be accurately detected.

Furthermore, because the second conductive layers 3041 are made of nanosilver lines or carbon nanotubes which have exceptional bendability, the second conductive layers 3041 can be patterned to be strip-shaped as shown in FIG. 6. The second conductive layers 3041 are parallel to and evenly spaced apart from each other on the bottom side of the cover film 3042 and are disposed on a same plane. An end of each of the second conductive layers 3041 is connected to a metal wire 3043 configured to provide an input voltage, while each of the second conductive layers 3041 corresponds to a different input voltage. The other end of each of the second conductive layers 3041 is connected to an electrode 3044 configured to connect to ground. In a direction perpendicular to an extending direction of the second conductive layers 3041, two ends of the first conductive layer 302 are respectively connected to two other electrodes, wherein one electrode is configured to provide a reference voltage, and the other electrode is configured to connect to ground, as shown in FIG. 6 and FIG. 7. When the cover film 3042 is pressed and deformed by fingers or touch pens, the second conductive layers 3041 are also deformed to contact the first conductive layer 302. Meanwhile, electrical resistances of the second conductive layers 3041 and the first conductive layer 302 are changed. When the change is detected by the touch screen, coordinates of touch points on the first conductive layer 302 and the second conductive layers 3041 can be respectively tracked, thereby concisely confirming positions of the touch points on the cover film 3042. Different from the second embodiment, in the present embodiment, different reference voltages are applied to different second conductive layers 3041, thereby concisely confirming positions of touch points on different second conductive layers 3041. Therefore, multiple touch points can be accurately detected.

In the above flexible display devices, the resistive touch screens provided by the above embodiments replace capacitive touch screens, and materials and structures of the resistive touch screens are improved. A problem that touch accuracy of conventional capacitive touch screens is low is solved, and a flexible display device having high accuracy, an ability to detect multiple touch points, and a long lifetime can be realized.

The present disclosure has been described with a preferred embodiment thereof. The preferred embodiment is not intended to limit the present disclosure, and it is understood that many changes and modifications to the described embodiment can be carried out without departing from the scope and the spirit of the disclosure that is intended to be limited only by the appended claims.

What is claimed is:

1. A resistive touch screen, comprising:
a substrate;
a first conductive layer disposed on the substrate;
a plurality of spacer points disposed on the first conductive layer; and
a film assembly disposed on the spacer points;
wherein the film assembly comprises a cover film and second conductive layer disposed on a bottom side of the cover film, and the second conductive layer is disposed on a same plane; and
a material of the second conductive layer is a nanosilver line or a carbon nanotube.

2. The resistive touch screen of claim 1, wherein a material of the first conductive layer is a nanosilver line or a carbon nanotube.

3. The resistive touch screen of claim 1, wherein materials of the spacer points are transparent insulating resins.

4. The resistive touch screen of claim 1, wherein in a first direction, an end of the first conductive layer is connected to an electrode configured to provide an input voltage.

5. The resistive touch screen of claim 4, wherein in the first direction, another end of the first conductive layer is connected to an electrode configured to connect to ground.

6. The resistive touch screen of claim 5, wherein in a second direction perpendicular to the first direction, an end of the second conductive layer is connected to an electrode configured to provide an input voltage.

7. The resistive touch screen of claim 6, wherein in the second direction, another end of the second conductive layer is connected to an electrode configured to connect to ground.

8. The resistive touch screen of claim 1, wherein a material of the cover film is polyimide.

9. The resistive touch screen of claim 1, wherein a number of the second conductive layer is plural.

10. The resistive touch screen of claim 9, wherein the second conductive layers are parallel to and evenly spaced apart from each other on the bottom side of the cover film.

11. The resistive touch screen of claim 10, wherein the second conductive layers are patterned to be strip-shaped.

12. The resistive touch screen of claim 9, wherein an end of each of the second conductive layers is connected to a metal wire configured to provide an input voltage.

13. The resistive touch screen of claim 12, wherein each of the second conductive layers corresponds to a different input voltage.

14. The resistive touch screen of claim 13, wherein another end of each of the second conductive layers is connected to an electrode configured to connect to ground.

15. The resistive touch screen of claim 10, wherein in a direction perpendicular to an extending direction of the second conductive layers, an end of the first conductive layer is connected to an electrode configured to provide an input voltage.

16. The resistive touch screen of claim 15, wherein in the direction perpendicular to the extending direction of the second conductive layers, another end of the first conductive layer is connected to an electrode configured to connect to ground.

17. A flexible display device, comprising:
an organic light-emitting diode (OLED) device;
a polarizer disposed on the OLED device; and
the resistive touch screen of claim 1 disposed on the polarizer.

18. The flexible display device of claim 17, wherein the OLED device comprises a substrate, and an anode, a hole transport layer, a luminescent layer, an electron transport layer, and a cathode, which are sequentially disposed on the substrate.

19. The flexible display device of claim 17, wherein the polarizer is attached to the OLED device by an optically clear adhesive.

20. The flexible display device of claim 17, wherein the polarizer is attached to the resistive touch screen by an optically clear adhesive.
